(19) United States
(12) Patent Application Publication
(10) Pub. No.: US 2025/0007510 A1
(43) Pub. Date: Jan. 2, 2025

(54) CONFIGURABLE TRAFFIC CONTROL CIRCUITS IN MESH NETWORK NODES TO MITIGATE VOLTAGE DROOP AND RELATED METHODS

(71) Applicant: Microsoft Technology Licensing, LLC, Redmond, WA (US)

(72) Inventors: Ann Hampton THOMAS, Raleigh, NC (US); Thomas BASNIGHT, Raleigh, NC (US); Thomas DETWILER, Huntsville, AL (US)

(21) Appl. No.: 18/216,974

(22) Filed: Jun. 30, 2023

(51) Int. Cl. H03K 17/082; H03K 3/84

(52) U.S. Cl. CPC H03K 17/0822; H03K 3/84

(57) ABSTRACT

A traffic control circuit in a node of a mesh network receives indications that circuit switching in the area of the node needs to be reduced and selectively inhibits traffic in selected channels of the network segments in a configurable manner to mitigate a voltage droop while allowing traffic to continue to the extent possible. The indications of circuit switching may include indicators of traffic generated in the node or in another node and an indicator that the power rail voltage level has dropped to a lower threshold. The traffic control circuit may determine a traffic reduction is needed based on combinations of the indicators. Based on configurable selections, the traffic control circuit may cause traffic to be inhibited in certain channels of network segments. A configurable linear feedback shift register may be employed to inhibit traffic in each channel according to a configured traffic profile.

### FIELD OF THE DISCLOSURE

The technology of the disclosure relates generally to reducing voltage droop in an integrated circuit and, more particularly, to minimizing current spikes by controlling circuit switching.

### BACKGROUND

To enable technologies that require high performance processing capabilities in a small sized package, the number of processing circuits provided in an integrated circuit (IC) chip has continued to increase. One approach to handling the large amount of data transferred between the many processing circuits in an IC is to employ a mesh network in which each of the processing circuits is coupled to a node of the network and data is passed from node to node. The levels of circuit switching due to data traffic at any given moment varies from node to node depending on the respective processing circuits. Thus, the power needs can shift frequently and the aggregate power level can rise suddenly. In such situations, the demand for current on the power rail providing a power supply voltage to the processing circuits increases suddenly. The power distribution network within the IC may have a capacitance that discharges in response to sudden current increases, causing a voltage level on the power supply rail to droop temporarily. To avoid having the power supply voltage provided to the processing circuits drop below a minimum voltage, below which the processing circuitry may not continue to operate normally, the nominal voltage level maintained on the power rail may be constantly maintained at a higher level to provide a voltage margin. However, maintaining a higher nominal voltage level on the power rail increases the power consumption of the IC chip, which may cause heat related problems and will reduce battery life in mobile devices. Circuits and methods for avoiding voltage droop in the nodes in a mesh network without simply increasing voltage would save power and avoid excessive heat generation.

### SUMMARY

Aspects disclosed in the detailed description include configurable traffic control circuits in mesh network nodes to mitigate voltage droop. Related methods of configurably controlling traffic in mesh network nodes to mitigate voltage droop are also disclosed. Processing circuits on integrated circuit (IC) chips, such as system-on-chip (SoC) devices, may be interconnected by a mesh network, with each processing circuit coupled to a network node. Sudden increases in circuit switching in the processing circuits and/or segments of the network coupled to the node can create a sudden increase in the demand for current in and around the node, which can cause a voltage droop in the local power supply rail. An exemplary traffic control circuit in the node receives indications that circuit switching in the area of the node needs to be reduced and selectively inhibits traffic in selected channels of the network segments in a configurable manner to mitigate a voltage droop while allowing traffic to continue to the extent possible. In some examples, the indications of a need for circuit switching may include indicators of traffic generated in the node or in another node and an indicator that the power rail voltage level has dropped to a lower threshold. The traffic control circuit may determine a reduction in traffic is needed based on a combination of the indicators and, based on a configurable selection, cause traffic to be inhibited in certain channels of one or more network segments. In some examples, the traffic in each channel may be inhibited according to a configured traffic profile, which may include employing a configurable linear feedback shift register (LFSR).

In this regard, an IC chip is disclosed. The IC chip includes a first node coupled to a plurality of segments of a mesh network, wherein each segment of the plurality of segments couples to the first node and to a respective adjacent node and comprises a plurality of channels configured to, independent of each other, transmit data to the respective adjacent node. The IC chip further includes the first node comprising a traffic control circuit comprising a plurality of indicator inputs, the traffic control circuit is configured to receive indicator signals related to power consumption in the IC chip; and, in response to the indicator signals, selectively inhibit data transmission in a subset of channels of the plurality of channels of at least one segment of the plurality of segments.

In another aspect, a method in an IC chip is disclosed. The method includes in a first node coupled to a plurality of segments of a mesh network, wherein each segment of the plurality of segments couples to the first node and to a respective adjacent node, and each segment comprises a plurality of channels configured to, independent of each other, transmit data to the respective adjacent node. The method further includes receiving indicator signals related to power consumption in the IC chip and, in response to the indicator signals, selectively inhibit data transmission in a subset of channels of the plurality of channels of at least one segment of the plurality of segments.

### BRIEF DESCRIPTION OF THE DRAWING FIGURES

FIG. 1 is a block diagram of an integrated circuit, including nodes interconnected in a mesh network;

FIG. 2 is a graph illustrating voltage changing over time in response to a voltage droop in an integrated circuit in response to first, second, and third-order voltage droops;

FIG. 3 is a block diagram of a node coupled to a plurality of channels of a mesh network and processing circuits coupled to the node;

FIG. 4 is a block diagram of a node including a plurality of router circuits controlling ingress and egress traffic on individual channels of the segments coupled to the node in FIG. 3 of a mesh network;

FIG. 5 is a block diagram of the traffic control circuit to configurably inhibit data transmissions in a subset of the channels of at least one segment coupled to the node of FIGS. 3 and 4 to mitigate a voltage droop;

FIG. 6 is a flowchart of a method of the exemplary traffic control circuit to inhibit traffic in a node in a mesh network on an IC to mitigate a voltage droop;

FIG. 7 is a block diagram of an exemplary traffic monitor circuit in the traffic control circuit of FIG. 5 configured to receive indicator signals and configurably determine a subset of channels of the segments in which data transmissions are selectively inhibited;

FIG. 8 is a logic circuit diagram of one example of a traffic inhibitor of the traffic control circuit in FIG. 5, including a linear feedback shift register (LFSR) and profile configuration registers for selectively inhibiting traffic in a pattern of cycles; and

FIG. 9 is a block diagram of an exemplary processor-based system that can include an integrated circuit (IC) chip, including nodes in a mesh network, each node including an exemplary traffic control circuit and traffic inhibitors to mitigate voltage droop, as shown in FIGS. 5, 7, and 8.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include configurable traffic control circuits in mesh network nodes to mitigate voltage droop. Related methods of configurably controlling traffic in mesh network nodes to mitigate voltage droop are also disclosed. Processing circuits on integrated circuit (IC) chips, such as system-on-chip (SoC) devices, may be interconnected by a mesh network, with each processing circuit coupled to a network node. Sudden increases in circuit switching in the processing circuits and/or segments of the network coupled to the node can create a sudden increase in the demand for current in and around the node, which can cause a voltage droop in the local power supply rail. An exemplary traffic control circuit in the node receives indications that circuit switching in the area of the node needs to be reduced and selectively inhibits traffic in selected channels of the network segments in a configurable manner to mitigate a voltage droop while allowing traffic to continue to the extent possible. In some examples, the indications of a need for circuit switching may include indicators of traffic generated in the node or in another node and an indicator that the power rail voltage level has dropped to a lower threshold. The traffic control circuit may determine a reduction in traffic is needed based on a combination of the indicators and, based on a configurable selection, cause traffic to be inhibited in certain channels of one or more network segments. In some examples, the traffic in each channel may be inhibited according to a configured traffic profile, which may include employing a configurable linear feedback shift register (LFSR).

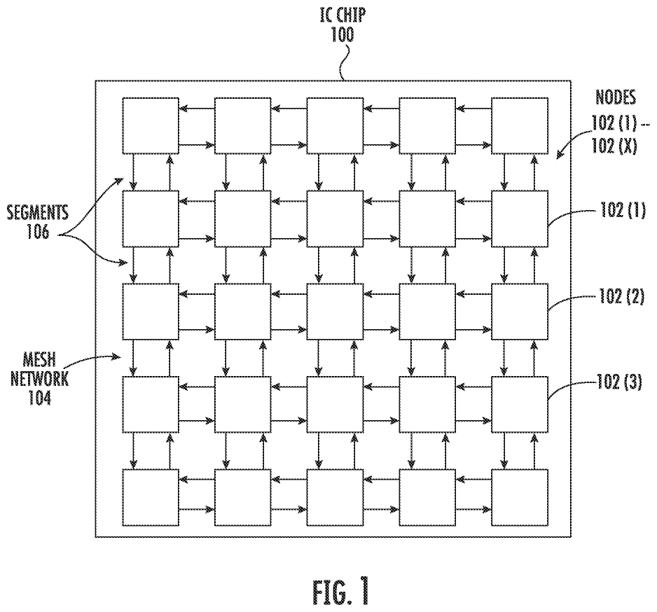

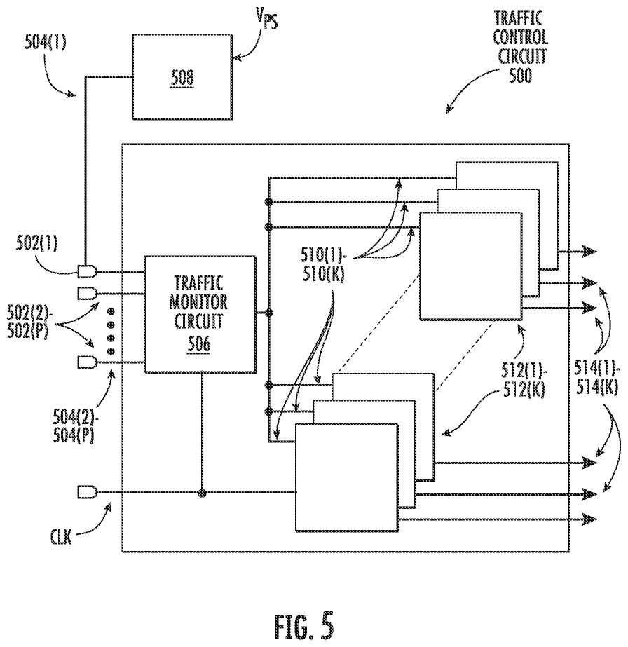

Before describing exemplary aspects of a traffic control circuit 500 that selectively inhibits data transmissions from nodes in a mesh network in response to indications of power-related conditions or events, with reference to FIGS. 5-7, details of an IC chip 100 in which the traffic control circuit 500 may be employed are first provided with reference to FIGS. 1-4. The IC chip 100, which may be a SOC, may include many processing circuits (not shown here) that are each coupled to one of a plurality of nodes 102(1)-102(X) in a mesh network 104. The nodes 102 are coupled to each other by segments 106 of the mesh network 104. Due to the segments 106 having relatively long wire lengths extending from one node 102 to another, a significant amount of power may be consumed by drivers in each node 102 transmitting data over the segments 106 in each cycle of a system clock CLK, where the system clock is employed to clock sequential circuits in the IC chip 100.

Consuming a significant amount of power in a node 102 in a short period of time (e.g., a high power consumption rate) imposes a demand for a high level of current to be provided by a power supply rail providing power to the node 102. In circumstances in which there is a sudden change in the node 102 from a low power consumption state to a higher power consumption state, there may be a sudden increase in the current demanded from the power rail. A sudden increase in current (i) in a short period of time (t), known as a di/dt event, may discharge any capacitance within the power distribution system in a region of the IC chip 100 or within the entire IC chip 100 before a power management circuit external to the IC chip 100 can respond to provide more power.

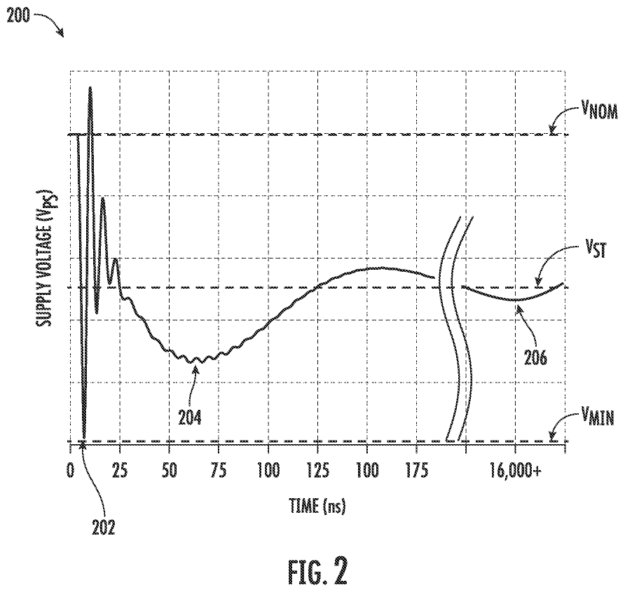

As the rate of change of power consumption increases (e.g., corresponding to a high rate of change of current), the more severe the di/dt event. As a result of such discharge, the power supply voltage on the power rail may suddenly drop when the available charge is consumed. When the voltage in the processing circuits drops below a minimum threshold, the processing circuits and data drivers may not operate in an expected manner, causing malfunctions in the IC chip 100. Such a drop in the power supply voltage is known as a voltage droop and is discussed in more detail with reference to FIG. 2.

FIG. 2 is graph 200 illustrating an example of a power supply voltage V_{PS} on a power supply rail in an IC chip without the exemplary traffic control circuit 500 in FIG. 5. FIG. 2 shows the power supply voltage V_{PS} changing over time (shown in nanoseconds (ns)) in response to a voltage droop. The graph 200 shows that a voltage droop reaction to a di/dt event may have up to three stages, referred to here as first, second, and third-order voltage droops, which can be identified by low points 202, 204, and 206, respectively, in the power supply voltage V_{PS}. These low points 202, 204, and 206 are each related to depletion of capacitance provided in the power distribution network to the IC chip 100 at different distances from the nodes 102. For example, the first-order droop shown as the low point 202 corresponds to a discharge of the capacitance of the power distribution network on the IC chip 100 itself. Capacitance on the IC chip 100 may be provided by coupling capacitors. Outside the IC chip 100, first-level power capacitors are typically coupled to the same substrate as the IC chip 100 in an IC package (not shown) or are otherwise located physically close to the IC chip 100. The low point 202 in the power supply voltage V_{PS} occurs before the charge from the first-level power capacitors can reach the power supply network internal to the IC chip 100. As the charge from the first-level power capacitors reaches the power supply network, the power supply voltage V_{PS} recovers and begins to stabilize. However, if the condition persists and/or is severe enough, the first-level power capacitors may also be fully discharged, leading to the second low point 204. In some examples, the capacitance of the first-level power capacitors is larger than the capacitance of the internal power supply network (e.g., the coupling capacitors), so the time to discharge the first-level power capacitors is longer, causing the second low point 204 to be reached more slowly.

A power management chip or voltage regulator (not shown) may be coupled to the IC package substrate for providing power to the IC chip 100. The power management chip is typically located farther from the IC chip 100 than the first-level power capacitors. Adjacent to the power management chip, the power distribution network providing power to the IC chip 100 includes one or more second-level power capacitor(s) having even greater capacitance than the first-level power capacitor(s). The second-level power capacitor(s) may also discharge before the second-level power capacitors coupled to the power management chip can provide charge to meet the current level demanded in the IC chip 100. The transition from the discharge of the second-level power capacitor(s) to a stabilization voltage V_{ST} of the power supply voltage V_{PS} is shown in FIG. 2 as the third low point 206. The power supply voltage V_{PS} will slowly recover from the stabilization voltage V_{ST} back to the nominal supply voltage V_{NOM} as each of the coupling capacitors, first-level power capacitors, and second-level power capacitors are recharged unless there is another di/dt event.

As shown in the example in FIG. 2, the first low point 202 causes the greatest reduction in the power supply voltage V_{PS}. In other examples, depending on relative capacitances of on-chip coupling capacitors and the first-level power capacitors, the low point 204 of the second order voltage droop may be lower than the low point 202. As noted above, circuits may begin to operate abnormally or unexpectedly as the power supply voltage V_{PS} drops below a minimum threshold voltage V_{MIN}. To avoid malfunctions in the circuits of the IC chip 100 when such voltage droops occur, the nominal supply voltage V_{NOM} provided to the IC chip 100 is set high enough that none of the first low point 202, the second low point 204, and the third low point 206 of the power supply voltage V_{PS} is below the minimum threshold voltage V_{MIN}. However, the nominal supply voltage V_{NOM}, which is determined in this example based on the first low point 202, is significantly higher than the minimum threshold voltage V_{MIN} needed to keep the circuits in the IC chip 100 operating normally. Since the power consumption of the IC chip 100 is based on the power supply voltage V_{PS}, which is elevated above the minimum threshold voltage V_{MIN} due to the voltage droop, it would be preferable to reduce the voltage droop, to reduce the nominal supply voltage V_{NOM} and reduce power consumption. Reducing power consumption reduces power-related heating and improves battery life in mobile devices that include the IC chip 100. Therefore, it would be beneficial to employ the traffic control circuit 500 and methods to mitigate voltage droop by avoiding sudden changes in the current level (e.g., di/dt events).

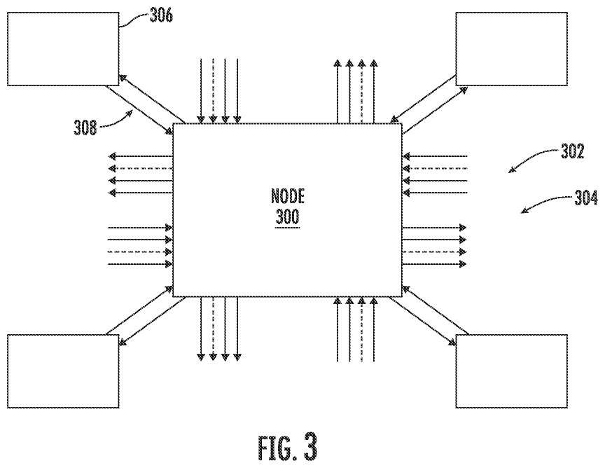

FIG. 3 is a block diagram illustrating an exemplary node 300 coupled to a plurality of segments 302 of a mesh network 304. The node 300 is coupled to processing circuits 306 by interfaces 308. The node 300 may be any of the nodes 102 in FIG. 1, and the segments 302 may be the segments 106 in FIG. 1. FIG. 3 is provided to show more detail of the environment in which the traffic control circuit 500 in FIG. 5 may be employed to mitigate voltage droops, which includes receiving indications of events and/or conditions that are related to power levels and changes in power levels and, in response to the indications, inhibiting data transmissions from the node in at least one cycle of a number of consecutive cycles of the system clock CLK.

The processing circuits 306 may include any kind of processor, processor core, and/or data storage circuits (e.g., cache memories or register files). The processing devices may quickly process large amounts of data based on sequences of instructions. The instructions and raw data need to be transferred into the node 300, and the processed data needs to be transferred out over the mesh network 304. In addition to all the data transmissions (“traffic”) needed to keep the multiple processing circuits 306 operating without wasted cycles, data may be transferred from a processing circuit 306 in the node 300, which may be the first node 102(1) in FIG. 1, to a second node 102(3), through an intermediate node 102(2), thereby further increasing the traffic level into and out of the intermediate node 102(2).

In this regard, power consumption in and around the node 300 is primarily due to the processing circuits 306 as well as traffic through the node 300. In particular, a large portion of the power consumption around the node 300 may be due to data transmissions (e.g., data egresses) from the node 300 because the long wires of the segments 302 from the node 300 to an adjacent node (see FIG. 1) have high capacitance, they require a large amount of charge in each cycle (e.g., to transition from a low voltage to a high voltage).

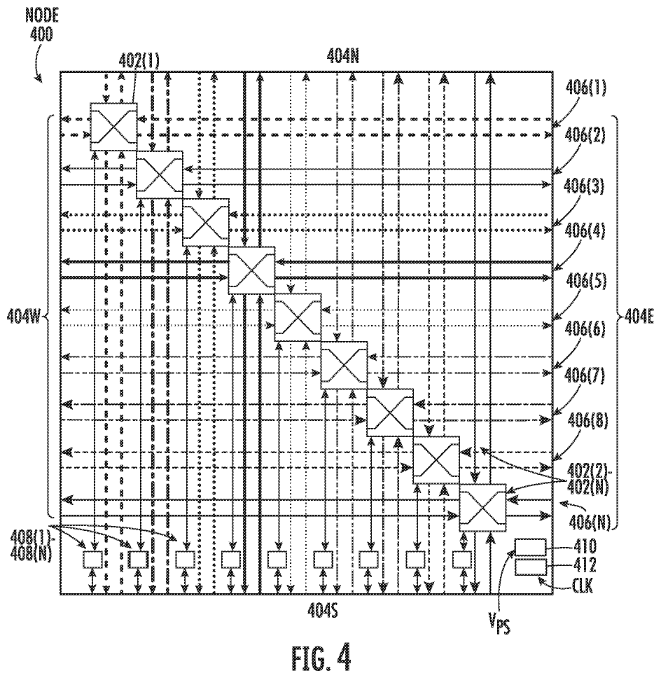

FIG. 4 is a block diagram of an exemplary node 400 illustrating a plurality of router circuits 402(1)-402(N) for controlling ingress and egress of data (referred to herein as “traffic”) on segments 404N, 404E, 404W, and 404S. The segments 404N, 404E, 404W, and 404S may be referred to generically or collectively herein as “segments 404”. The node 400 may be the node 300 in FIG. 3 or any of the nodes 102(1)-102(X) in FIG. 1. Each of the segments 404 couples to the node 400 and to a respective adjacent node that is adjacent to the node 400. For example, referring to FIG. 1, the nodes 102(1) and 102(3) are adjacent to the node 102(2).

Each of the segments 404, which corresponds to the segments 302 in FIG. 3, includes channels 406(1)-406(N). Thus each of the plurality of router circuits 402(1)-402(N) is coupled to one of the plurality of channels 406(1)-406(N) in each of the plurality of segments 404. For example, the router circuit 402(1) is coupled to the channel 406(1) in each of the segments 404(N), 404(E), 404(W), and 404(S). The router circuits 402(1)-402(N) are capable of coupling incoming data from any of the segments 404 or from a processing circuit (see processing circuits 306 of FIG. 3) coupled to the node 400 to the corresponding outgoing channel of any one or more of the other segments 404.

Each channel 406(1)-406(N) may also be referred to as a bus for the transmission of multiple bits of binary data signals and/or control signals. The router circuits 402(1)-402(N) may each include driver circuits for each outgoing or transmitted data bit (also referred to herein as a data egress) and receiver circuits (not shown) for each incoming data bit (referred to herein as a data ingress). The driver and receiver circuits receive the system clock CLK for synchronizing the reception and transmission of signals. Thus, the plurality of channels 406(1)-406(N) may be configured to transmit data and receive data in each cycle of the system clock CLK.

Although the node 400 includes nine (9) router circuits 402(1)-402(N), where N=9, for the nine channels 406(1)-406(N), the node 400 may include any number of router circuits appropriate to the number of channels in the segments 404. The respective channels 406(1)-406(N) may have different widths or numbers of bits. For example, channel 406(1) may be 16 bits in width, while channel 406(2) may be sixteen (16), twenty-four (24), thirty-six (36), or any other number of bits in width. As shown in FIG. 1, some of the nodes 102(1)-102(X) are coupled to two (2) or three (3) segments 106, depending on their position in the mesh network 104. Such nodes would have fewer segments 106 than are shown in FIG. 4. It should be understood that FIG. 4 is provided primarily to show one example of the arrangement of router circuits 402(1)-402(N) and the channels 406(1)-406(N) but, additionally, the node 400 may include any other appropriate logic, such as router circuit controllers 408(1)-408(N) to respectively control the router circuits 402(1)-402(N) in a manner discussed below. The router circuit controllers 408(1)-408(N) may be employed to schedule and control data transmission from the router circuits 402(1)-402(N). The node 400 also includes a power node 410 coupled to a power rail (not shown) to provide a power supply voltage Vₚs to the node 400. FIG. 4 also shows a clock circuit 412 in the node 400 for providing the system clock CLK.

FIG. 5 is a block diagram of an exemplary traffic control circuit 500 to selectively inhibit data transmissions in a subset of channels of at least one segment 404 of a mesh network on an IC, such as in the segments 302 of the mesh network 304 in FIG. 3 and the channels 406(1)-406(N) of the segments 404 shown in FIG. 4, to mitigate a voltage droop. The description of FIG. 5 may additionally refer to features of the node 300 in FIG. 3 and the node 400 in FIG. 4.

The traffic control circuit 500 includes a plurality of indicator inputs 502(1)-502(P) configured to receive indicator signals 504(1)-504(P) related to power consumption in the IC chip 100. Each of the indicator signals 504(1)-504(P) indicates a condition or event related to power provided to the node 400. Based on the indicator signals 504(1)-504(P), the traffic control circuit 500 selectively inhibits data transmission in a pattern of cycles of the system clock CLK in a number of consecutive cycles of the system clock CLK. That is, to reduce power consumption in the node 400 in FIG. 4 over a configurable number M of consecutive clock cycles to reduce or avoid a di/dt event, the traffic control circuit 500 inhibits data transmission in certain cycles among the M consecutive cycles based on a configurable pattern. In this regard, inhibiting data transmission in a cycle of the system clock CLK indicates that data transmission is not enabled or otherwise blocked and, therefore, does not occur in that cycle. As explained below, in some examples, the pattern comprises a pseudo-random pattern of cycles among the M consecutive cycles.

The traffic control circuit 500 includes a traffic monitor circuit 506 that receives the indicator signals 504(1)-504(P), which may come from a variety of sources. The respective indicator signals 504(1)-504(P) may be evaluated in a configurable manner, depending on the information indicated. For example, the traffic control circuit 500 may determine that data transmissions should be inhibited to reduce power consumption based on a power supply voltage Vₚs on a power node 410 in the node 400 in FIG. 4. In this regard, the IC chip 100 in FIG. 1 may also include a voltage comparator circuit 508 (shown in FIG. 5) that compares the power supply voltage Vₚs on a power rail or power node 410 (either near the node 400 or at the IC level) to a voltage threshold and generates an indication of the power supply voltage V_{PS} in the indicator signal 504(1). Alternatively, the voltage comparator circuit 508 may compare a power supply voltage V_{PS} on a power rail providing power to the IC chip 100 to the low voltage threshold. In some examples, the voltage comparator circuit 508 may compare the voltage V_{PS} to multiple voltage threshold levels to identify a voltage range and may generate the indicator signal 504(1) with a value indicating the range of the voltage V_{PS}. Different values of the indicator signal 504(1) may cause the traffic control circuit 500 to react more aggressively or less aggressively.

In some examples, other factors are considered separately or together with the indicator signal 504(1) to determine how to selectively inhibit data transmissions in the node 400. For example, the indicator signals 504(2)-504(P) may indicate that a data transmission will be happening. In some examples, the plurality of router circuits 402(1)-402(N) (or the router circuit controllers 408(1)-408(N)) generate some of the indicator signals 504(1)-504(P) received at the indicator inputs 502(1)-502(P) indicating that there are one or more pending data transmissions (e.g., that data are scheduled to be transmitted in a next cycle or cycles). In some examples, the processing circuits 306 in FIG. 3 may be a source of the indicator signals 504(2)-504(P), indicating that data in the processing circuit 306 is going to be provided to the node 400 for a data transmission (e.g., from the processing circuit 306) to an adjacent node in the next cycle or cycles. Additional examples of the sources of the indicator signals 504(2)-504(P) may include the nodes (e.g., 102(1), 102(3), as shown in FIG. 1) adjacent to the node 400. The indicator signals 504(2)-504(P) may indicate that the adjacent nodes are or will be transmitting data (e.g., egress data) to the node 400, which may require the node 400 to transmit the data to another location. In some examples, the adjacent nodes may indicate data transmissions from another node and received in the adjacent node (e.g., ingress data), which may be forwarded to the node 400 for further transmission (e.g., to another adjacent node in the mesh network).

It can be understood that some examples of the indicator signals 504(2)-504(P) are more likely to cause data transmissions from the node 400 and, therefore, may not be considered equally by the traffic monitor circuit when determining how to respond. Similarly, the respective indicator signals 504(2)-504(P) may indicate data transmissions having different timing. For example, an indication from the router circuit controllers 408(1)-408(N) may indicate a data transmission is imminent in the next cycle or two, whereas an indication or ingress data from an adjacent node can indicate that a data transmission from the node 400 may occur in multiple cycles. In this regard, the traffic monitor circuit 506 can be configured to apply different weights to the indicator signals 504(1)-504(P) and/or may react differently according to specific combinations or conditions.

In response to the indicator signals 504(1)-504(P), the traffic monitor circuit 506 generates traffic inhibit signals 510(1)-510(K), which are provided to a plurality of traffic inhibitor circuits 512(1)-512(K), included in the traffic control circuit 500. In some examples, the number K of traffic inhibitor circuits 512(1)-512(K) corresponds one-to-one to the router circuits 402(1)-402(N) (e.g., K=N). In other examples, the number K of traffic inhibitor circuits 512(1)-512(K) may not be the same as the number N of router circuits 402(1)-402(N). For example, one of the traffic inhibitor circuits 512(1)-512(K), may control multiple router circuits 402(1)-402(N). Thus, each of the traffic inhibitor circuits 512(1)-512(K) corresponds to at least one of the channels 406(1)-406(N) in a segment 404 coupled to the node 400. In response to the traffic inhibit signals 510(1)-510(K), the traffic inhibitor circuits 512(1)-512(K) generate enable signals 514(1)-514(K), which may be provided to the router circuit 402(1)-402(N) directly to enable or disable a driver circuit (not shown), or provided to the router circuit controllers 408(1)-408(N) that control the router circuits 402(1)-402(N).

The traffic monitor circuit 506 can be configured to determine the timing of the traffic inhibit signals 510(1)-510(K) and also determine the aggressiveness of the response indicated by the traffic inhibit signal 510, depending on the indicator signals 504(1)-504(P). For example, depending on the indicator signals 504(1)-504(P), the traffic monitor circuit 506 may determine that data transmission only needs to be inhibited in a limited number of the router circuits 402(1)-402(N), and may determine such limited number.

In addition, in another aspect, the traffic inhibit signals 510(1)-510(K) may indicate the severity or aggressiveness of the traffic inhibitor circuits 512(1)-512(K) should exercise with regard to inhibiting data transmissions. The traffic monitor circuit 506 is configured to determine, based on the indicator signals 504(1)-504(P), a value for the traffic inhibit signals 510(1)-510(K) to each of a subset of the channels 406(1)-406(N). A subset of the channels 406(1)-406(N) includes any non-zero integer number of channels from one (1) up to N−1. The traffic monitor circuit 506 may also determine to inhibit data transmissions in all the channels 406(1)-406(N). In some examples, the traffic inhibit signals 510(1)-510(K) are multi-bit binary signals. In some examples, the traffic inhibit signals 510(1)-510(K) may be updated every cycle of the system clock CLK in response to the indicator signals 504(1)-504(P).

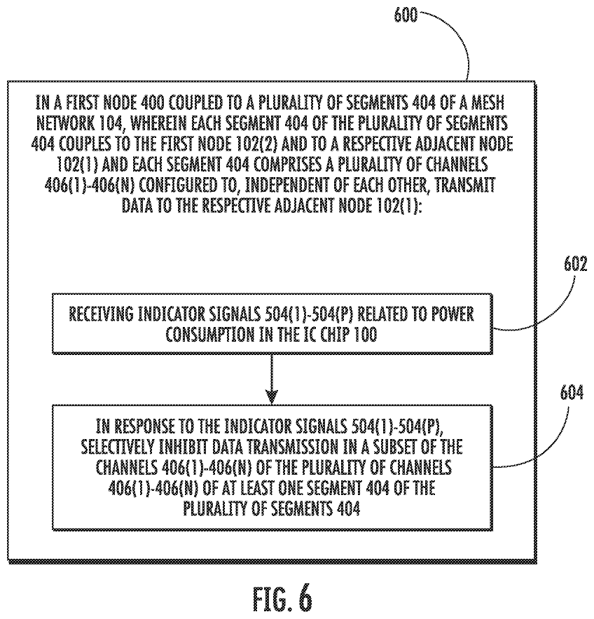

FIG. 6 is a flowchart of a method 600 of the exemplary traffic control circuit 500 to selectively inhibit data transmission in a node 300 and 400 (as shown in FIGS. 3 and 4) in a mesh network 104 on an IC chip 100 (in FIG. 1) to mitigate a voltage droop. The method includes in a first node 400 coupled to a plurality of segments 404 of a mesh network 104, wherein each segment 404 of the plurality of segments 404 couples to the first node 400 and to a respective adjacent node 102(1), and each segment 404 comprises a plurality of channels 406(0)-406(N) configured to, independent of each other, transmit data to the respective adjacent node 102(1): receiving indicator signals 504(1)-504(P) related to power consumption in the IC chip 100 (block 602); and in response to the indicator signals 504(1)-504(P), selectively inhibit data transmission in a subset of channels 406(0)-406(N) of the plurality of channels 406(0)-406(N) of at least one segment 404 of the plurality of segments 404 (block 604).

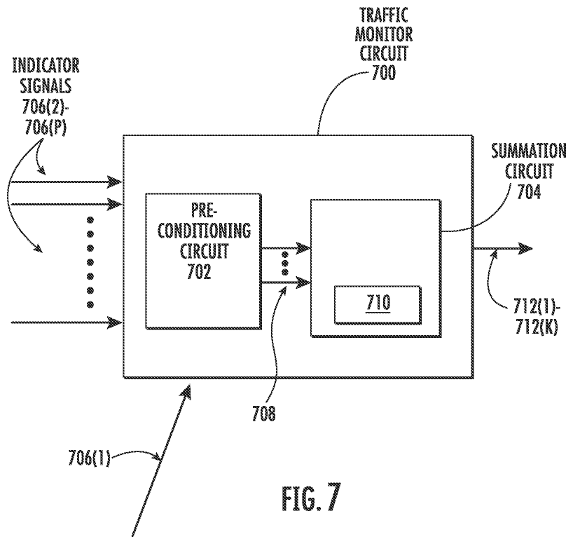

FIG. 7 is a block diagram of an exemplary traffic monitor circuit 700 corresponding to the traffic monitor circuit 506 in the traffic control circuit 500 of FIG. 5 and features of the nodes 300 and 400 in FIGS. 3 and 4. Thus, the description of FIG. 7 includes references to FIGS. 3-5. The traffic monitor circuit 700 is configured to receive indicator signals 706(1)-706(P) and configurably determine a subset of channels 406(0)-406(N) of the segments 404 in which data transmissions are selectively inhibited.

The traffic monitor circuit 700 includes a preconditioning circuit 702 and a summation circuit 704. The preconditioning circuit 702 receives indicator signals 706(1)-706(P), which correspond to the indicator signals 504(1)-504(P) in FIG. 5. As discussed above, the indicator signals 706(1)-706(P) may have several different sources and, therefore, provide indications of different types of information. While the indicator signal 706(1) may be an indication of a power supply voltage V_{PS}, the remaining indicator signals 706(2)-706(P) each provide an indication that there may be or will be (unless inhibited by the traffic control circuit 500) a data transmission from the node 400 in FIG. 4 based on a condition or event detected in circuits that are in communication with the node 400 in FIG. 4. In this regard, each of the indicator signals 706(1)-706(P) is related to power consumption in the IC chip 100. The indicator signal 706(1) from the voltage comparator circuit 508 indicates the power supply voltage V_{PS}, which is directly indicative of power consumption in the IC chip 100 and, more particularly, may be indicative of power consumption in the node 400. In contrast, the indicator signals 706(2)-706(P) are indicators of power consumption that will or may occur due to data transmissions generated from the node 400. Data transmissions may occur due to data being processed in the processing circuits 306 in FIG. 3, due to data being received from an adjacent node, and due to data being sent to the node 400 from an adjacent node. As noted above, a future data transmission in the node 400 can even be indicated by data arriving (received) in an adjacent node because that arriving data may eventually be forwarded to the node 400 for processing and/or retransmission.

The preconditioning circuit 702 preconditions the indicator signals 706(1)-706(P) before preconditioned indications 708 are provided to the summation circuit 704. The preconditioning circuit 702 may apply weights corresponding to the different types of indicator signals 706(1)-706(P). For example, each of the channels 406(1)-406(N) in FIG. 4 may have different numbers of bits. Thus, inhibiting data transmission in one of the channels 406(1)-406(N) may have a significantly different impact to current demand than inhibiting data transmission in another. The preconditioning circuit 702 may also or alternatively normalize, prioritize, synchronize, and/or consider other circumstances or events related to the indicator signals 706(1)-706(P) (e.g., frequency, sources, patterns, rates of change, etc.). The summation circuit 704 receives the preconditioned indications 708 and determines an appropriate response. Specifically, each preconditioned indication 708 may indicate an extent to which data transmissions should be reduced as well as the period of time over which such reduction needs to occur to avoid a di/dt event that would cause a voltage droop.

An appropriate response may include reducing a level of circuit switching, reducing a rate of increase of circuit switching, and/or delaying an increase in circuit switching, for example. In this context, as noted previously, data transmissions are a type of circuit switching responsible for a large amount of current consumption. Shutting down all data transmissions from the node 400 could potentially have a significant negative impact on performance in the IC chip 100, which is strongly avoided. Therefore, the summation circuit 704 determines, based on the preconditioned indications 708, a subset of the channels 406(1)-406(N) in which data transmissions can be inhibited to best effectuate a reduction, stabilization or gradual increase of power consumption (to the extent necessary) with minimal impact to performance.

A response may be generated based on a sum of the preconditioned indications 708 within a single cycle, a sum over a number of cycles, or some algorithm that recognizes changes to the preconditioned indications 708. In some examples, situations or circumstances indicated by the preconditioned indications 708 may be identified during testing, and a best appropriate response may be identified by designers. To take advantage of such prior knowledge, the summation circuit 704 may include a subset configuration register 710 that can be programmed to identify a best subset of the channels 406(1)-406(N) in which data transmissions can be inhibited in recognized situations to have an optimal compromise of voltage droop and performance impact. As a result, the traffic monitor circuit 700 generates traffic inhibit signals 712(1)-712(K), which may be the traffic inhibit signals 510(1)-510(K) in FIG. 5.

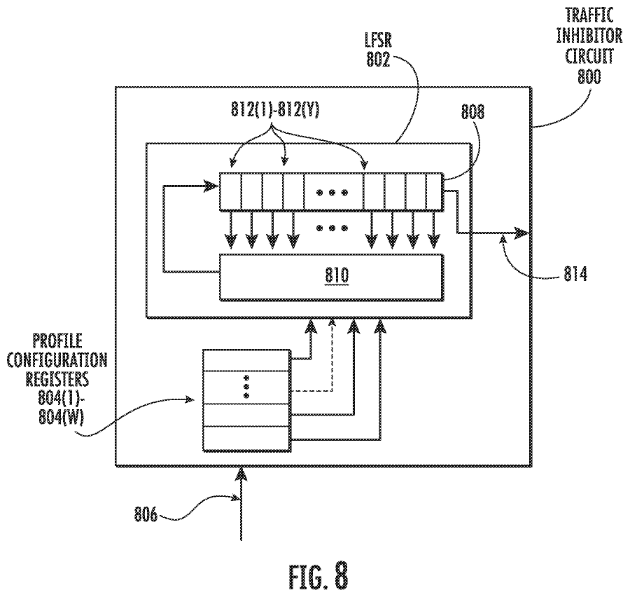

FIG. 8 is a logic circuit diagram of one example of a traffic inhibitor circuit 800 that may be employed in the traffic control circuit 500 in FIG. 5, including a linear feedback shift register (LFSR) 802 and profile configuration registers 804(1)-804(W) for selectively inhibiting data transmission in a pattern of cycles of the system clock CLK. The description of FIG. 8 may include references to features in any of FIGS. 3-5 and 7. The traffic inhibitor circuit 800 may be any of the traffic inhibitor circuits 512(1)-512(K) in the traffic control circuit 500 in FIG. 5. The traffic inhibitor circuit 800 can receive a traffic inhibit signal 806 on a traffic inhibit input 807. The traffic inhibit signal 806 may be one of the traffic inhibit signals 510(1)-510(K) in FIG. 5 or the traffic inhibit signals 712(1)-712(K) in FIG. 7. In examples in which the traffic inhibitor circuit 800 corresponds to one of the subsets of channels 406(1)-406(N) to be inhibited, which are identified by the traffic monitor circuit 700, the traffic inhibit signal 806 causes the traffic inhibitor circuit 800 to selectively inhibit data transmission on the corresponding one of the channels 406(1)_406(N). The traffic inhibitor circuit 800 can be configured to selectively inhibit data transmissions in at least one of the router circuits 402(1)-402(N) in FIG. 4 in the node 400.

The traffic inhibitor circuit 800 can be configured to inhibit data transmission in a pattern of cycles of the system clock CLK among a configurable number (e.g., 1 to 36) of consecutive cycles of the system clock CLK. For example, a pattern of cycles in which data transmissions are inhibited may be a pseudo-random pattern. The traffic inhibitor circuit 800 may be configured to determine the pattern. In some examples, the pattern may be determined by the LFSR 802, which includes a shift register 808 and configurable logic 810.

As previously noted, the traffic inhibit signal 806 may be a multi-bit signal having multiple values. In some examples, each of the profile configuration registers 804(1)-804(W) includes a programmed entry for one of the values of the traffic inhibit signal 806. The programmed entry can control the configurable logic 810 to provide a unique pattern to the shift register 808. For example, the shift register 808 may contain a series of binary digits 812(1)-812(Y) (e.g., zeroes (“0”) and ones (“1)). The binary digit 812(Y) may be shifted out in each cycle of the system clock CLK and provided as enable signal 814 to the corresponding router circuit 402(1)-402(N) (or the router circuit controllers 408(1)-408(N)) to inhibit or not inhibit a data transmission. In some examples, the enable signal 814, being a one (1), may inhibit or disable the data transmission, and the enable signal 814, being a zero (0), does not inhibit transmission. In some examples, the enable signal 814, being a zero (0), may inhibit or disable the data transmission. Data transmission may be inhibited in a same cycle or a next cycle after the enable signal 814 is provided, for example. In some examples, the enable signal 814 controls a driver circuit in an interface of the corresponding one of the router circuits 402(1)-402(N) to the channels 406(1)-406(N). It should be understood that in cycles in which the enable signal 814 is not in a state for inhibiting data transmission, data transmissions may proceed normally, as needed, which may include no data transmission.

Although the shift register 808 may contain Y bits, the traffic inhibitor circuit 800 may be configured, based on the profile configuration registers 804(1)-804(W), to provide a pattern of cycles of any desired length in which data transmission is inhibited in one or more of the cycles. The traffic inhibit signal 806 may have a plurality of values. For example, in response to receiving a first value of the traffic inhibit signal 806, the traffic inhibitor circuit 800 may allow data transmissions to occur in every cycle without interruption. In response to a second value, for example, the traffic inhibitor circuit 800 may inhibit data transmission (e.g., disable the driver) every fifth (5^{th}) clock cycle of the system clock CLK. In response to a third value, for example, the traffic inhibitor circuit 800 may disable the driver in a first cycle of the system clock CLK and then in seven (7) (e.g., randomly selected) of the next thirty-three (33) cycles and repeat this periodically. In response to a fourth value, the traffic inhibitor circuit 800 may aggressively inhibit data transmission, such that data transmission is only allowed in six (6) out of a sequence of thirty-four (34) consecutive cycles, for example. Each of such profiles is programmed into an entry of the profile configuration registers 804(1)-804(W). The traffic inhibitor circuit 800 may be configured to stop inhibiting data transmission after one sequence of a profile or continue repeating the sequence as long as the value in response to continuing to receive the same value of the traffic inhibit signal 806. The profiles described above are merely examples, and any pattern of any length for inhibiting data transmission may be programmed into the profile configuration registers 804(1)-804(W) and generated by the LFSR 802.

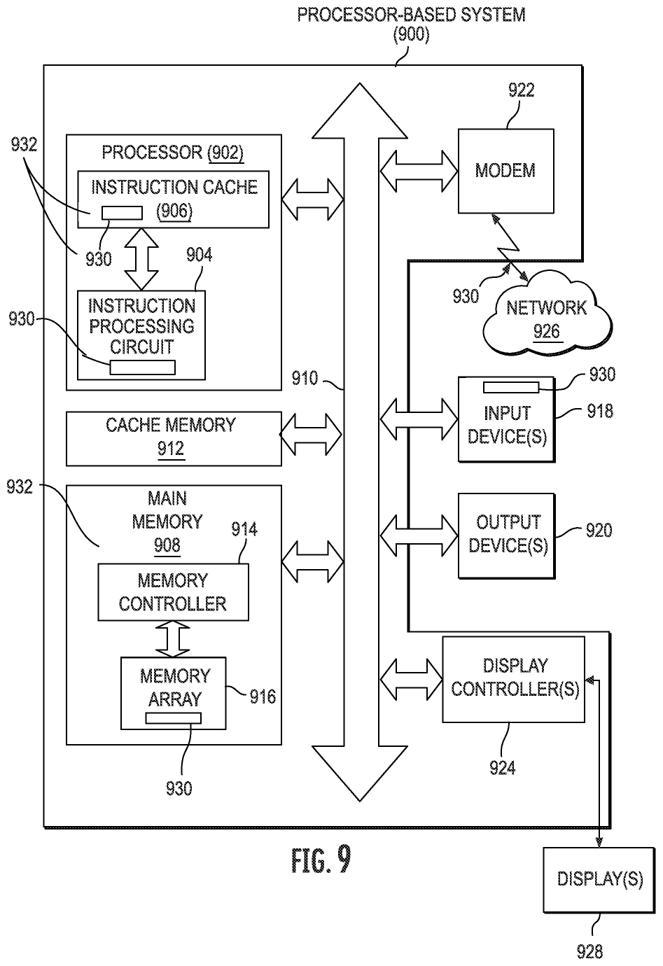

FIG. 9 is a block diagram of an exemplary processor-based system 900 that includes a processor 902 (e.g., a microprocessor) that includes an instruction processing circuit 904 and a traffic control circuit to configurably inhibit data transmissions in a subset of channels of at least one segment of a mesh network coupled to the node, as illustrated in FIGS. 5, 7, and 8. As an example, any of the processor-based system 900, the processor 902, and the instruction processing circuit 904 can be the IC chip 100 in FIG. 1. The processor-based system 900 may be a circuit or circuits included in an electronic board card, such as a printed circuit board (PCB), a server, a personal computer, a desktop computer, a laptop computer, a personal digital assistant (PDA), a computing pad, a mobile device, or any other device, and may represent, for example, a server, or a user's computer.

In this example, the processor 902 represents one or more general-purpose processing circuits, such as a microprocessor, central processing unit, or the like. The processor 902 is configured to execute processing logic in instructions for performing the operations and steps discussed herein. In this example, the processor 902 includes an instruction cache 906 for temporary, fast access memory storage of instructions accessible by the instruction processing circuit 904. Fetched or prefetched instructions from a memory, such as from the cache memory 912 over a system bus 910, are stored in the instruction cache 906. The instruction processing circuit 904 is configured to process instructions fetched into the instruction cache 906 and process the instructions for execution.

The processor 902 and the cache memory 912 are coupled to the system bus 910 and can intercouple peripheral devices included in the processor-based system 900. As is well known, the processor 902 communicates with these other devices by exchanging address, control, and data information over the system bus 910. For example, the processor 902 can communicate bus transaction requests to a memory controller 914 in the main memory 908 as an example of a slave device. Although not illustrated in FIG. 9, multiple system buses 910 could be provided, wherein each system bus constitutes a different fabric. In this example, the memory controller 914 is configured to provide memory access requests to a memory array 916 in the main memory 908. The memory array 916 is comprised of an array of storage bit cells for storing data. The main memory 908 may be a read-only memory (ROM), flash memory, dynamic random access memory (DRAM), such as synchronous DRAM (SDRAM), etc., and a static memory (e.g., flash memory, static random access memory (SRAM), etc.), as non-limiting examples.

Other devices can be connected to the system bus 910. As illustrated in FIG. 9, these devices can include the main memory 908, one or more input device(s) 918, one or more output device(s) 920, a modem 922, and one or more display controllers 924, as examples. The input device(s) 918 can include any type of input device, including but not limited to input keys, switches, voice processors, etc. The output device(s) 920 can include any type of output device, including but not limited to audio, video, other visual indicators, etc. The modem 922 can be any device configured to allow exchange of data to and from a network 926. The network 926 can be any type of network, including but not limited to a wired or wireless network, a private or public network, a local area network (LAN), a wireless local area network (WLAN), a wide area network (WAN), a BLUETOOTH™ network, and the Internet. The modem 922 can be configured to support any type of communications protocol desired. The processor 902 may also be configured to access the display controller(s) 924 over the system bus 910 to control information sent to one or more displays 928. The display(s) 928 can include any type of display, including but not limited to a cathode ray tube (CRT), a liquid crystal display (LCD), a plasma display, etc.

The processor-based system 900 in FIG. 9 may include a set of instructions 930 to be executed by the processor 902 for any application desired according to the instructions. The instructions 930 may be stored in the main memory 908, processor 902, and/or instruction cache 906 as examples of a non-transitory computer-readable medium 932. The instructions 930 may also reside, completely or at least partially, within the main memory 908 and/or within the processor 902 during their execution. The instructions 930 may further be transmitted or received over the network 926 via the modem 922, such that the network 926 includes the computer-readable medium 932 while the computer-readable medium 932 is shown in an exemplary embodiment to be a single medium, the term “computer-readable medium” should be taken to include a single medium or multiple media (e.g., a centralized or distributed database and/or associated caches and servers) that stores the one or more sets of instructions. The term “computer-readable medium” shall also be taken to include any medium that is capable of storing, encoding, or carrying a set of instructions for execution by the processing device and that causes the processing device to perform any one or more of the methodologies of the embodiments disclosed herein. The term “computer-readable medium” shall accordingly be taken to include, but not be limited to, solid-state memories, optical medium, and magnetic medium.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product or software that may include a machine-readable medium (or computer-readable medium) having stored thereon instructions, which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes a machine-readable storage medium (e.g., ROM, random access memory (“RAM”), a magnetic disk storage medium, an optical storage medium, flash memories, etc.), and the like.

Unless specifically stated otherwise and as apparent from the previous discussion, it is appreciated that throughout the description, discussions utilizing terms such as “processing,” “computing,” “determining,” “displaying,” or the like refer to the action and processes of a computer system, or similar electronic computing device, that manipulates and transforms data and memories represented as physical (electronic) quantities within the computer system's registers into other data similarly represented as physical quantities within the computer system memories or registers or other such information storage, transmission, or display devices.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. An integrated circuit (IC) chip comprising:
a first node coupled to a plurality of segments of a mesh network, wherein each segment of the plurality of segments:
couples to the first node and to a respective adjacent node; and
comprises a plurality of channels configured to, independent of each other, transmit data to the respective adjacent node,
wherein the first node comprises a traffic control circuit comprising a plurality of indicator inputs, the traffic control circuit configured to:
receive indicator signals related to power consumption in the IC chip; and
in response to the indicator signals, selectively inhibit data transmission in a subset of channels of the plurality of channels of at least one segment of the plurality of segments.

2. The IC chip of claim 1, wherein:
each channel of the plurality of channels is configured to transmit data in each cycle of a system clock; and
the traffic control circuit is further configured to selectively inhibit data transmission in a pattern of cycles of the system clock among a configurable number of consecutive cycles of the system clock.

3. The IC chip of claim 2, wherein the pattern of cycles of the system clock comprises a pseudo-random pattern of cycles among the first number of consecutive cycles.

4. The IC chip of claim 2, the traffic control circuit further comprising a plurality of traffic inhibitor circuits, each corresponding to at least one channel of the plurality of channels in a segment of the plurality of segments coupled to the first node, wherein each traffic inhibitor circuit of the plurality of traffic inhibitor circuits is configurable to determine the pattern of cycles.

5. The IC chip of claim 4, wherein each traffic inhibitor circuit comprises a linear feedback shift register (LFSR) configured to determine the pattern of cycles.

6. The IC chip of claim 5, wherein each traffic inhibitor circuit further comprises:
a traffic inhibit input configured to receive a traffic inhibit signal having one of a plurality of values; and
configurable profile registers, each configured to control the LFSR to determine the pattern of cycles corresponding to each of the plurality of values of the traffic inhibitor signal.

7. The IC chip of claim 1, the first node further comprising a plurality of router circuits, wherein:
each router circuit of the plurality of router circuits is coupled to one of the plurality of channels in each segment of the plurality of segments; and
the traffic control circuit is further configured to control the plurality of router circuits to selectively inhibit data transmission in the subset of channels of the plurality of channels of the at least one segment of the plurality of segments.

8. The IC chip of claim 1, the traffic control circuit further comprising a traffic monitor circuit configured to:
receive the indicator signals; and
determine, based on the indicator signals, whether to generate a traffic inhibit signal to each of the subset of channels.

9. The IC chip of claim 8, the traffic monitor circuit further configured to determine, based on the indicator signals, one of a plurality of values for the traffic inhibit signal to each of the subset of channels.

10. The IC chip of claim 9, the traffic monitor circuit comprising a subset configuration register, wherein the traffic monitor circuit is further configured to:
determine the subset of channels of the plurality of channels for each of the plurality of values of the traffic inhibit signal based on the subset configuration register.

11. The IC chip of claim 1, further comprising a voltage comparator circuit configured to:
compare a power supply voltage on a power rail coupled to the first node to a voltage threshold; and
generate an indication of the power supply voltage,
wherein the indicator signals received at one indicator input of the plurality of indicator inputs of the traffic control circuit comprise the indication of the power supply voltage.

12. The IC chip of claim 7, wherein the plurality of router circuits generates a first plurality of the indicator signals received at the plurality of indicator inputs of the traffic control circuit to indicate one or more pending data transmissions.

13. The IC chip of claim 1, wherein each channel of the plurality of channels in each segment of the plurality of segments is further configured to receive data transmissions from the respective adjacent node and the indicator signals received at the plurality of indicator inputs of the traffic control circuit comprise indications of data transmissions from the respective adjacent node to the first node over at least one of the plurality of channels.

14. The IC chip of claim 1, wherein each channel of the plurality of channels in each segment of the plurality of segments is further configured to receive data transmissions from the respective adjacent node and the indicator signals received at the plurality of indicator inputs of the traffic control circuit comprise indications of data transmissions from another node received in the adjacent node.

15. The IC chip of claim 1, further comprising a plurality of processing circuits coupled to the first node, wherein the indicator signals received at the plurality of indicator inputs of the traffic control circuit comprise indications of data transmissions from the processing circuits to an adjacent node.

16. The IC chip of claim 1, wherein the indicator signals indicate a condition or event related to power provided to the first node.

17. A method in an integrated circuit (IC) chip, the method comprising, in a first node coupled to a plurality of segments of a mesh network, wherein each segment of the plurality of segments couples to the first node and to a respective adjacent node and each segment comprises a plurality of channels configured to, independent of each other, transmit data to the respective adjacent node:
receiving indicator signals related to power consumption in the IC chip; and
in response to the indicator signals, selectively inhibit data transmission in a subset of channels of the plurality of channels of at least one segment of the plurality of segments.

18. The method of claim 17, further comprising:
transmitting data in the plurality of channels in each cycle of a system clock; and
selectively inhibiting data transmission in a pattern of cycles of a system clock among a first number of consecutive cycles of the system clock.

19. The method of claim 18, wherein the pattern of cycles of the system clock comprises a pseudo-random pattern of cycles among the first number of consecutive cycles of the system clock.

20. The method of claim 18, further comprising, determining the pattern of cycles in each of a plurality of traffic inhibitor circuits in the traffic control circuit, wherein each traffic inhibitor corresponds to at least one channel of the plurality of channels in a segment of the plurality of segments coupled to the first node.

21. The method of claim 20, wherein determining the pattern of cycles in each traffic inhibitor circuit further comprises employing a linear feedback shift register (LFSR).

22. The method of claim 21, further comprising, in each traffic inhibitor circuit:
receiving a traffic inhibit signal; and
based on configurable profile registers, each configured to control the LFSR, determining the pattern of cycles corresponding to each value of the traffic inhibitor signal.

23. The method of claim 17, further comprising, controlling a plurality of router circuits, each coupled to one channel of the subset of channels, to selectively inhibit data transmission in the subset of channels of the plurality of channels of at least one segment.

24. The method of claim 17, further comprising, in a traffic monitor circuit in the traffic control circuit:
receiving the indicator signals; and
determining, based on the indicator signals, whether to generate a traffic inhibit signal to each of the subset of channels.

25. The method of claim 24, further comprising determining, in the traffic monitor circuit based on the indicator signals, a value for the traffic inhibit signal to each of the subset of channels.

26. The method of claim 25, further comprising determining the subset of channels of the plurality of channels for each of the values of the traffic inhibit signal based on a subset configuration register in the traffic monitor circuit.

27. The method of claim 17, further comprising:
comparing, in a voltage comparator circuit, a power supply voltage on a power rail coupled to the first node to a voltage threshold; and
generating an indication of the power supply voltage,
wherein the indicator signals received at one indicator input of the plurality of indicator inputs of the traffic control circuit comprise the indication of the power supply voltage.

28. The method of claim 23, wherein the indicator signals received at the plurality of indicator inputs of the traffic control circuit comprise indications of one or more pending data transmissions from the plurality of router circuits.

29. The method of claim 27, further comprising receiving, in each channel of the plurality of channels in each segment of the plurality of segments, indicator signals comprising indications of data transmissions from the respective adjacent node.

30. The method of claim 17, wherein the indicator signals indicate a condition or event related to power provided to the first node.
